(19) United States
(12) Patent Application Publication
(10) Pub. No.: US 2009/0001537 A1
(43) Pub. Date: Jan. 1, 2009

(54) Gettering material for encapsulated microdevices and method of manufacture

(75) Inventor: Jeffery F. Summers, Santa Barbara, CA (US)

Correspondence Address: Jaquelin K. Spong, 2139 Dominion Way, Falls Church, VA, 22043, US

(73) Assignee: Innovative Micro Technology, Goleta, CA (US)

(21) Appl. No.: 11/819,338

(22) Filed: Jun. 27, 2007

(51) Int. Cl. H01L 23/26; H01L 21/00

(52) U.S. Cl. 257/682; 438/115; 257/E23.137

(57) ABSTRACT

A method for providing improved gettering in a vacuum encapsulated microdevice is described. The method includes designing a getter alloy to more closely approximate the coefficient of thermal expansion of a substrate upon which the getter alloy is deposited. Such a getter alloy may have a weight percentage of less than about 8% iron (Fe) and greater than about 50% zirconium, with the balance being vanadium and titanium, which may better match the coefficient of thermal expansion of a silicon substrate. In one exemplary embodiment, the improved getter alloy is deposited on a silicon substrate prepared with a plurality of indentation features, which increase the surface area of the substrate exposed to the vacuum. Such a getter alloy is less likely to delaminate from the indented surface of the substrate material during heat-activated steps, such as activating the getter material and bonding a lid wafer to the device wafer supporting the microdevice.

### CROSS REFERENCE TO RELATED APPLICATIONS

Not applicable.

### STATEMENT REGARDING FEDERALLY SPONSORED RESEARCH

Not applicable.

### STATEMENT REGARDING MICROFICHE APPENDIX

Not applicable.

### BACKGROUND

This invention relates to encapsulated integrated circuit and microelectromechanical systems (MEMS) devices. More particularly, this invention relates to the prevention, reduction, elimination or purification of outgassing and trapped gases in such devices.

The ability to maintain a low pressure or vacuum for a prolonged period in a microelectronic package is sought after in such diverse areas as display technologies, microelectromechanical systems (MEMS) and high density storage devices. For example, computers, displays, and personal digital assistants may all incorporate devices which utilize electrons to traverse a vacuum gap to excite a phosphor in the case of displays, or to modify a media to create bits in the case of storage devices, for example.

Microelectromechanical systems (MEMS) are very small moveable structures made on a substrate using lithographic processing techniques, such as those used to manufacture semiconductor devices. Microdevices may be moveable actuators, sensors, valves, pistons, or switches, for example, with characteristic dimensions of a few microns to hundreds of microns. One example of a microdevice is a microfabricated cantilevered beam, which may be used to detect the presence of a particular material, for example, a biological pathogen. By coating the MEMS cantilever with a suitable reagent, the pathogen may bind with the reagent resulting in mass added to the cantilevered beam. The additional mass may be detected by measuring a shift in the characteristic vibration frequency of the cantilevered beam. However, because air is viscous, the cantilevered beam may be required to operate in a vacuum, so that the viscosity of ambient air does not broaden the resonance peak.

In another example, the microdevice may be a detector or emitter of infrared (IR) radiation, so that the emitter may need to be surrounded by vacuum in order to reduce the absorption of the IR radiation by the atmosphere. Accordingly, microdevices such as cantilevered beams and IR emitters/detectors may require vacuum packaging, in order to increase the signal-to-noise level of the detector or the output of the emitter to an acceptable level.

The packaging of the microdevice may be accomplished by bonding a lid wafer with a device wafer. The microdevices, such as the cantilevered beams, are first fabricated on the device wafer. The lid wafer is then prepared by etching trenches or cavities in the lid wafer which will provide clearance for the microdevice on the device wafer. Before bonding, the lid wafer is aligned with the device wafer, so that the device cavity in the lid wafer is registered above the device on the device wafer, providing clearance for the height of the microdevice and for its anticipated range of motion.

The lid wafer and device wafer assembly may then be loaded into a wafer bonding chamber, which is then evacuated. The lid wafer is then permanently bonded to the device wafer with a hermetic bond, so that the evacuated environment within the device cavity does not equilibrate with the outside environment by leakage over time. The formation of this hermetic seal may require heating to temperatures in excess of 400 degrees centigrade.

One of the major problems with vacuum packaging of electronic devices, including MEMS is the continuous outgassing of hydrogen, water vapor, carbon monoxide, and other components found in ambient air, and from the internal components of the electronic or microdevice. Typically, to minimize the effects of outgassing, one uses gas-absorbing materials commonly referred to as getter materials. Generally a getter material is a metal alloy, for example, an alloy of zirconium (Zr), vanadium (V), and iron (Fe) such as that described in U.S. Pat. No. 4,312,669, incorporated by reference herein in its entirety, that is sputter deposited on the surface of the lid wafer. The getter material may be deposited on either or both of the lid wafer and the device wafer. The getter material may then be activated by heating to a predefined temperature, so that the getter desorbs or diffuses the gases already absorbed and is ready to function in the device.

### SUMMARY

When the getter material, deposited on a substrate surface, is heated to activate the getter, the temperature of the structure may reach 400 degrees centigrade or more. Heating of the getter may also occur when the device wafer is bonded to the lid wafer, in order to cure the adhesive. If the getter material has a substantially different coefficient of thermal expansion (CTE) relative to the substrate, the getter film may delaminate, peel or flake away from the substrate surface during this heating. The debris generated may interfere with the functioning of the device, or of the getter, or both. The tendency for the getter film to delaminate may be worse when it is deposited over rough or corrugated surfaces.

In order to prevent the delamination of the getter material from the device wafer or lid wafer when the wafers are heated for bonding or activation of the getter material, the getter material may be formulated so that its temperature coefficient of thermal expansion (CTEs) more closely matches that of the wafer substrate material. For example, if the wafer material is silicon with a CTE of 3 ppm per degree centigrade and the getter material is zirconium (Zr), vanadium (V), titanium (Ti) and iron (Fe), a relative weight percentage of 60/20/15/5 may create an alloy with a more closely matched CTE than the prior art composition of 50/25/15/10, manufactured by Getter Technologies International, Ltd. of Hong Kong, and as described, for example, at http://getters.com/ZirconiumVanadiumTitaniumIron.aspx. The ability of the novel formulation of the getter material to remain adhered to a surface may be particularly important when it is applied to a surface having corrugation, or indentation features formed therein, in order to increase the surface area of the getter. Such an indented surface is described more fully below, as well as in co-pending U.S. patent application Ser. No. 11/433,435 (Attorney Docket No. IMT-Getter, the '435 application), incorporated by reference herein in its entirety.

This alloy composition is a specific example of a more general formulation of an alloy composition which is adjusted to match the CTE of a wafer, while substantially maintaining the gettering ability of the alloy. A formulation such as, for example, greater than about 50% Zr, and less than about 8% Fe, with the balance of the material being vanadium and titanium, may more closely match the CTE of silicon, and therefore resist delamination.

The systems and methods therefore include determining the CTE of the intended substrate, and adjusting the getter alloy until it has a CTE that more closely approximates that of the substrate. For example, a silicon substrate has a measured CTE of about 3 ppm per degree. The getter composition of a ZrVTiFe getter is then adjusted to increase the Zr composition, with its relatively low CTE of 2.9 ppm per degree, and reduce the Fe composition, with its relatively high CTE of 11.6 ppm. Thus, the new alloy has a CTE that more closely matches silicon, and associated problems of delamination, cracking, and flaking of the getter alloy into the microdevice cavity are reduced or avoided. The getter is thereby better able to perform its intended function of absorbing impurity gases and reducing the pressure of the ambient environment in the microdevice cavity.

The new getter composition may be applied to an indented lid design, as disclosed in the incorporated '435 application. The indented lid design may have indentation features formed therein, which increase the surface area, and therefore the gettering ability of a getter material formed on the indented lid. Because of the details of the shape of the indented lid, matching the CTEs of the getter material with the lid substrate may provide particular benefits of promoting the adhesion of the getter material to the indented substrate.

These and other features and advantages are described in, or are apparent from, the following detailed description.

### BRIEF DESCRIPTION OF THE DRAWINGS

Various exemplary details are described with reference to the following figures, wherein:

FIG. 1 is a plan view of an exemplary device wafer;

FIG. 2 is a plan view of an exemplary lid wafer, showing indentation features in the device cavities according to a first exemplary embodiment;

FIG. 3 is a plan view of the exemplary lid wafer of FIG. 2 in greater detail;

FIG. 4 is a cross sectional view of the indentation features in the device cavity of the lid wafer in greater detail;

FIG. 5 is a cross sectional view of the indentation features in the device cavity of the lid wafer in greater detail, showing the deposition of the getter film;

FIG. 6 is a cross sectional view of an exemplary lid wafer and device wafer assembly;

FIG. 7 is a plan view of an exemplary lid wafer, showing indentation features in the device cavities according to a second exemplary embodiment; and

FIG. 8 is a flowchart of an exemplary method for manufacturing a vacuum encapsulated MEMS device.

### DETAILED DESCRIPTION

The systems and methods described herein may be particularly applicable to vacuum encapsulated moveable microelectromechanical (MEMS) devices, such as sensors, actuators, emitters, detectors, switches, cantilevers, or the like. However, they may also be applicable to any integrated circuit formed on a device wafer and encapsulated with a getter material under a lid wafer. Accordingly, the improved getter formulation may be applied to many other types of microdevices, as well as the specific embodiment described below.

Furthermore, the systems and methods are described with respect to an indented lid embodiment, wherein the improved getter material is deposited in a cavity having a plurality of indentation features formed therein. However, it should be understood that this embodiment is exemplary only, and that the improved getter material may be applied to other designs, such as an unindented lid. The improved getter material may be applied to a lid or device wafer with no device cavity formed therein, wherein the lid wafer is held aloft from the device wafer by a rigid standoff, for example. The systems and methods may also be applied to a device and lid system comprising 3 or more bonded substrates. Exemplary embodiments are described below, with the first portion directed to fabrication of the devices on the device wafer, the next portion directed to the fabrication of the lid wafer, then the deposition of the improved getter material, followed by the sealing of the device wafer with the lid wafer.

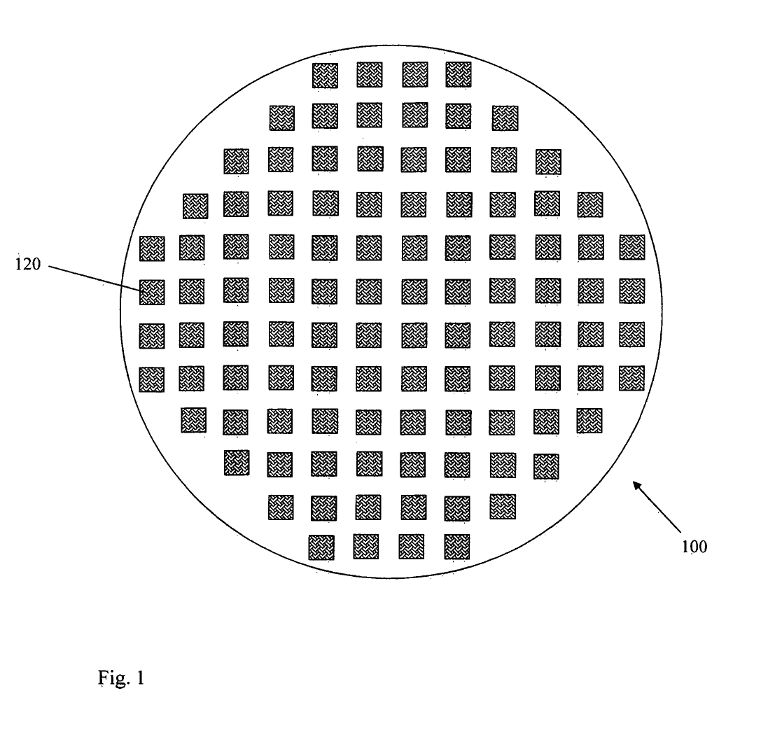

FIG. 1 is a diagram of an exemplary device wafer 100, upon which a plurality of microdevices 120 may be fabricated. The microdevices 120 may have a device pitch of, for example, about 10 mm so that about 12 microdevices may fit within a six inch device wafer 100. It should be understood that this situation is exemplary only, and that the microdevices may in general be much smaller, and that this relatively large size is shown for ease of depiction.

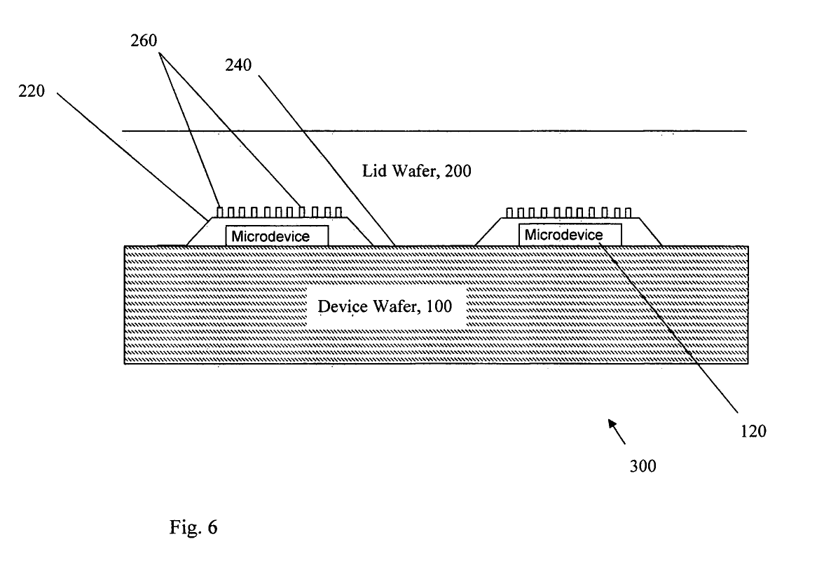

The device wafer 100 may be composed of any number of satisfactory substrate materials, such as silicon, gallium arsenide, silicon-on-insulator (SOI), glass, sapphire, and the like. In one embodiment, the device wafer 100 is silicon, about 675 μm thick, and the microdevice 120 may be an infrared (IR) emitter, such as that described in U.S. application Ser. No. 11/605,312 (Attorney Docket No. IMT-NiMn IR, the '312 application), incorporated by reference herein in its entirety. A plurality of like microdevices 120 may be formed on the surface of the device wafer 100, using, for example, surface machining processes. For example, the IR emitter microdevice may be fabricated by first forming a layer of platinum over a dielectric layer on a substrate, forming an array of holes in the platinum, and then annealing the platinum on the substrate. Finally, after etching a serpentine pattern in the platinum layer, the layer may emit IR radiation when current is driven through the serpentine pattern. Further details as to the fabrication of the IR emitter as the microdevices 120 are set forth in the incorporated '312 application. However, it should be understood that the microdevices 120 may be any of a number of devices other than the IR emitter described in the incorporated '312 application, such as accelerometers, sensors, actuators, and the like. Since the details of the microdevices 120 are not necessary to the understanding of the systems and methods described here, they are depicted only schematically in FIGS. 1 and 6.

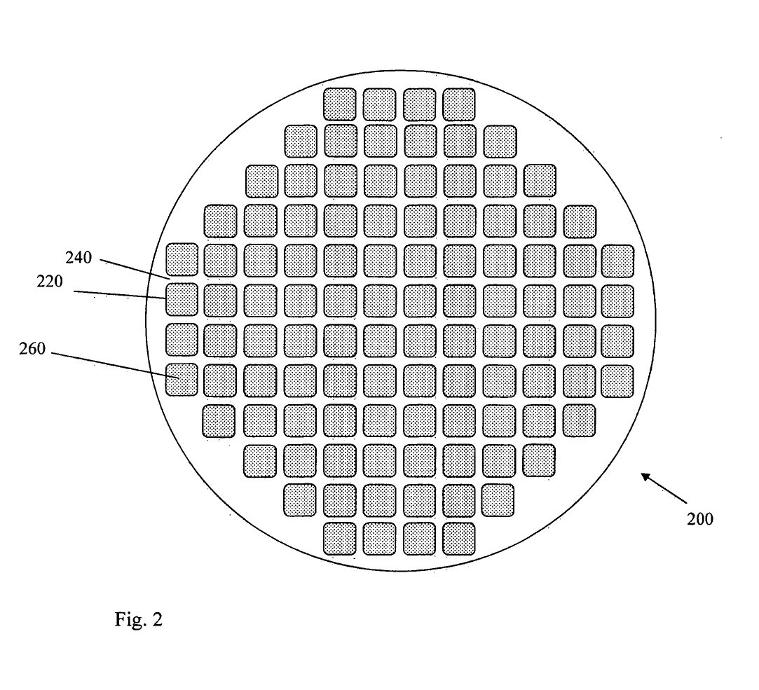

FIG. 2 is a diagram of an exemplary lid wafer 200 with a plurality of device cavities 220 formed therein. A “lid” wafer should be understood to mean a wafer which provides encapsulation for a device formed on a device wafer, and may or may not have any additional active structures on it. The device cavities 220 in the lid wafer 200 may be used to encapsulate the microdevices 120 formed on the device wafer 100, when the lid wafer 200 is sealed against the device wafer 100. The material of the lid wafer 200 may be high transmittivity float zone silicon, which may transmit a large fraction of the IR radiation produced by the IR emitter microdevice 120. However, for other applications not requiring transmittivity in the IR, other materials may be used for the lid wafer, including, for example, glass, standard doped silicon, Kovar (a nickel-cobalt ferrous alloy, with typically of 29% nickel, 17% cobalt, 0.2% silicon, 0.3% manganese, and 53.5% iron), Invar (an alloy of 64% iron and 36% nickel, with, optionally, some carbon and chromium), metal, and ceramic.

The pitch of the device cavities 220 may be the same as the pitch of the microdevices 120 formed on the device wafer 100. The device cavities 220 may be formed on one side of the lid wafer using a dry etch process, such as deep reactive ion etching (DRIE) or reactive ion etching (RIE). However, the device cavity 220 may also be formed using a cheaper, wet process such as a liquid chemical etch. For example, the lid wafer 200 may first be covered with photoresist and patterned to expose the portions of the lid wafer 200 which will be removed to form the device cavities 220. The photoresist may be developed, and the lid wafer submerged in a solution of potassium hydroxide (KOH) solution to etch the device cavities 220 to a depth of about 150 μm. It should be understood that any other depth may be chosen, in order to give adequate clearance for the any movement of the microdevice that might be required. The span of the cavity is chosen to allow an adequate perimeter around the microdevice and room for its movement, while still minimizing the wafer area lost to such overhead. The width of the device cavity may be, for example, about 6 mm.

The chemical etching may be isotropic, and may form the device cavity 220 in the lid wafer with a wall slope of about 57 degrees, that is, the angle defined by the sidewall and a line parallel to the plane of the wafer is about 57 degrees.

Within each device cavity may be a plurality of indentation features 260. The term “indentation feature” should be understood to mean one or more features formed on a surface of at least a portion of a surface of the device cavity, which extend to some depth into or out from the surface, such that their sidewalls give the device cavity more surface area than it would otherwise have. The word “indentation” is therefore not intended to refer to a specific shape of a hole or groove, but may instead refer to any feature which may be formed as one or more depressions in the device cavity surface. The indentation features 260 may be an array of blind holes, for example, etched into the device cavity surface. Furthermore, the term “indentation feature” may also refer to a feature formed by the deposition of material on the lid wafer, in order to form a set of pillars or posts, providing additional surface area. Such deposited indentation features may be formed by electroplating or ion beam deposition of the additional material onto the surface of the lid wafer. Although the indentation features are shown formed on the lid wafer, it should be understood that the indentation features may be formed either on the lid wafer or on the device wafer, or both.

In general, the indentation features may be substantially smaller than the dimensions of the device cavity, such that a plurality of indentation features may be placed within a single device cavity. For example, a characteristic dimension of the indentation features may be at least about ten times smaller than the width of the device cavity.

The indentation features 260 may be formed before or after the device cavity is formed. For example, the plurality of holes 260 may be formed on the otherwise flat surface of the lid wafer, before the formation of the device cavity 220. The holes 260 may be formed by, for example, patterning photoresist and DRIE or wet etching the lid wafer through the apertures in the patterned photoresist. Photoresist may then be reapplied to the lid wafer and patterned in areas corresponding to the device cavity. The device cavity may then be formed by DRIE or wet etching the surface which formed the lands between the plurality of small holes 260. In other exemplary embodiments, the indentation features may be formed in the device cavity surface when the lid wafer 200 is stamped or molded.

Alternatively, in another exemplary embodiment, the indentation features 260 may be formed after the device cavity 220 has been etched. After forming the device cavity 220, photoresist is reapplied to the lid wafer surface and patterned according to the locations and shapes of the indentation features 260. The indentation features 260 are then etched into the surface of the device cavity 220 using, for example, DRIE or wet etching.

Other alternative methods for making the indentation features 260 include ion milling, dry etching, stamping, and molding. Finally, the indentation features may be made by depositing material on the lid wafer 200. For example, features such as posts, columns or pillars may be deposited by electroplating or ion beam deposition, to create the indentation features.

In each of the exemplary embodiments described here, the indentation features are formed on the lid wafer. However, in other exemplary embodiments, the indentation features may be placed in an unused area of the device wafer, although this is typically less desirable as it may interfere with the efficient layout of devices on the device wafer.

In the exemplary embodiment described here, both the device wafer and the lid wafer may be, for example, silicon, which has a CTE of about 3 ppm per degree centigrade. Importantly, the getter material which is to be deposited over the indentation features 260 may have a formulation designed to better match the CTE of the substrate, such that the getter material adheres well to the substrate and better resists the tendency to delaminate.

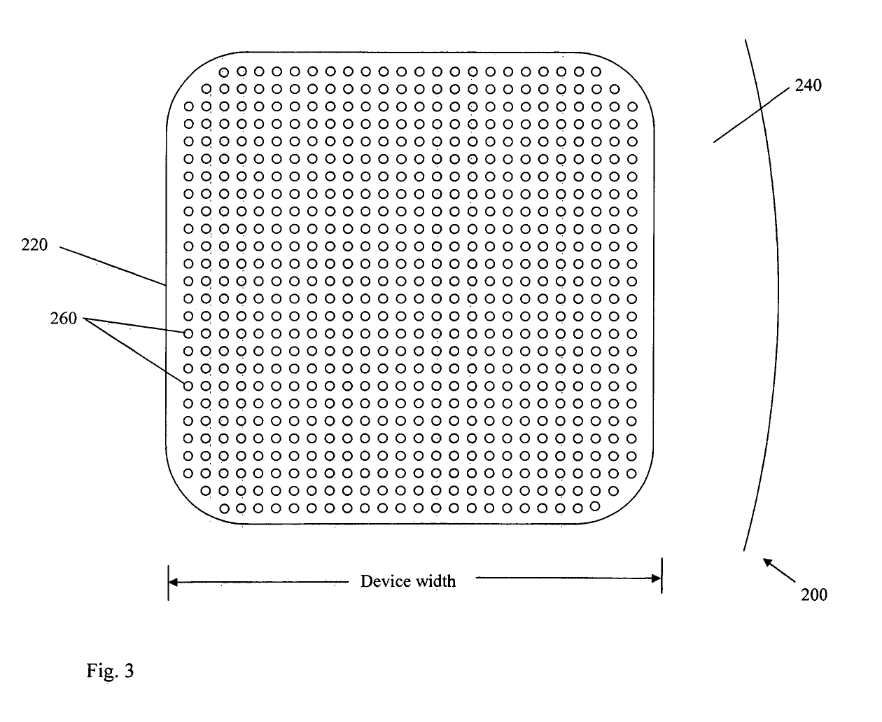

FIG. 3 is a plan view showing the exemplary lid wafer 200 in greater detail. The indentation features 260 are shown in the device cavity 220. According to FIG. 3, about 650 of the indentation features 260 may fit within the device cavity 220, with the device cavity 220 being about 6 mm in width. Accordingly, the indentation features may have a pitch of about 6 to about 250 μm or larger. For ease of depiction, the indentation features are depicted as being relatively large, having a diameter of about 100 μm. The only limit on the size of the indentation feature may be that for large features, a fewer number of them will then fit within the device cavity, reducing the amount of surface area added to the getter film. However, it should be understood that the indentation features may be much smaller, with a diameter of about 6 μm, for example.

Although FIGS. 2 and 3 show the indentation features formed only within the device cavity 220, it should be understood that the indentation features may also be formed outside of the device cavity 220, for example, over the entire surface of the lid wafer, as long as they do not interfere with the formation of a seal between the lid wafer and the device wafer. However, the getter material is typically only formed over the portion, of the indentation features 260 that are, within the device cavity 220. It should be understood that although the getter material and indentation features are described as applied to a lid wafer over a microdevice, this is only one exemplary embodiment, and the getter material may be applied to any other encapsulated microdevice, with or without an indented lid.

The seal between the lid wafer and the device wafer may be formed by applying an adhesive to surface 240 shown in FIGS. 2 and 3. The adhesive may be any material capable of forming a hermetic or vacuum seal between the lid wafer and the device wafer, thereby enclosing the device 120 within an evacuated device cavity 220. One example of a suitable adhesive is a glass frit with embedded rigid particles, as described in co-pending U.S. patent application Ser. No. 11/390,085 (Attorney Docket No. IMT-Standoff), incorporated by reference herein in its entirety.

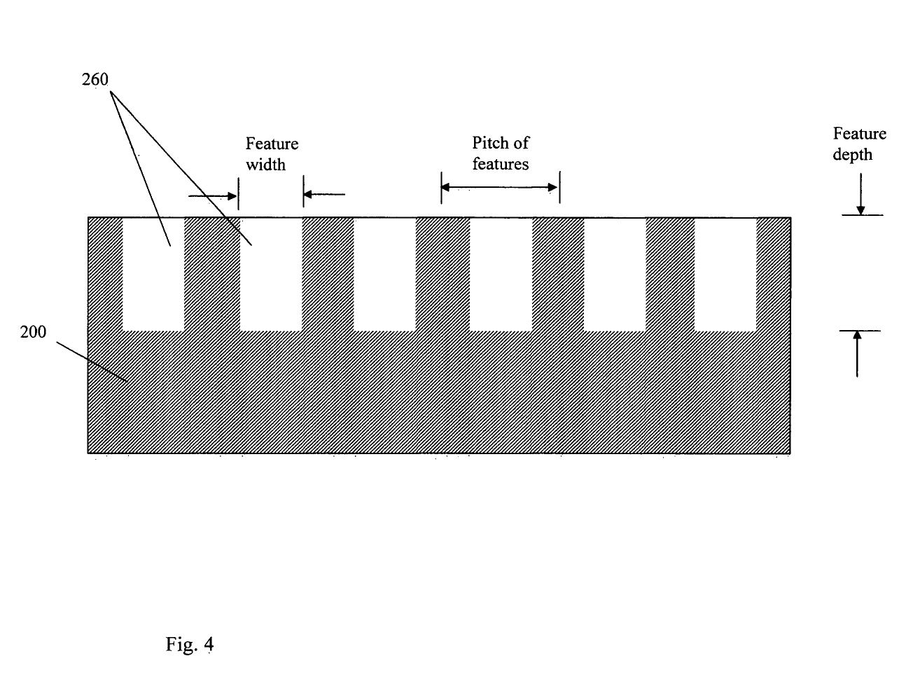

FIG. 4 is a cross sectional view showing the detailed dimensions of the indentation features 260. In this exemplary embodiment, the indentation features 260 are blind holes having a depth of about 8 μm and a diameter of about 6 μm. Accordingly, the aspect ratio, defined as the depth divided by the diameter of indentation features, is about 1.33 to 1. More generally, the indentation features may have aspect ratios less than about 3 to 1, and more preferably, less than about 2 to 1. For example, the blind holes may have diameters of about 5 μm to about 100 μm, and depths of about 8 μm to about 200 μm, with aspect ratios of about 2 to 1. More preferably, the blind holes may have a diameter of about 5 μm to about 10 μm, and a depth of about 8 μm to about 20 μm. The 2 to 1 aspect ratio may be the largest which will yield a deposited getter film having sufficient thickness to cover the sidewalls of the indentation features with a substantially uniform film, because of the self-shadowing effect of the sidewalls of the indentation feature 260 on the ends of the sidewall near the end of the blind hole. If the aspect ratio exceeds about 3 to 1, the coverage of the getter film may become excessively thin, particularly deep in the hole near the blind end, or not cover the sidewall uniformly.

Although specific dimensions are described for the formation of the array of blind holes, it should be understood that these dimensions are exemplary only, and that any of a range of other dimensions may be chosen, depending on the requirements of the application. Accordingly, the invention should not be limited to these particular embodiments.

In various exemplary embodiments, the indentation features 260 are disposed in a rectangular array. The pitch between the indentation features 260 may be nearly the diameter of the blind holes, such that their outer diameters nearly touch. Alternatively, the blind holes may be placed at a distance of about twice the diameter of the blind holes, such that the outer walls of the blind holes do not touch. The larger separation may result in a lid of greater mechanical strength which may resist cracking during further downstream handling and processing, although there will be less surface area available for the getter material 270 in this embodiment. The indentation features 260 may alternatively be disposed in a close-packed hexagonal array, or any other regular or irregular pattern. The pitch between the features in the array may also vary over different portions of the wafer surface, rather than being regularly spaced over the whole wafer surface. Finally, the indentation features 260 may be placed near the perimeter of the device cavity, in order to reduce their effect on the transmission of the generated IR radiation through the lid wafer.

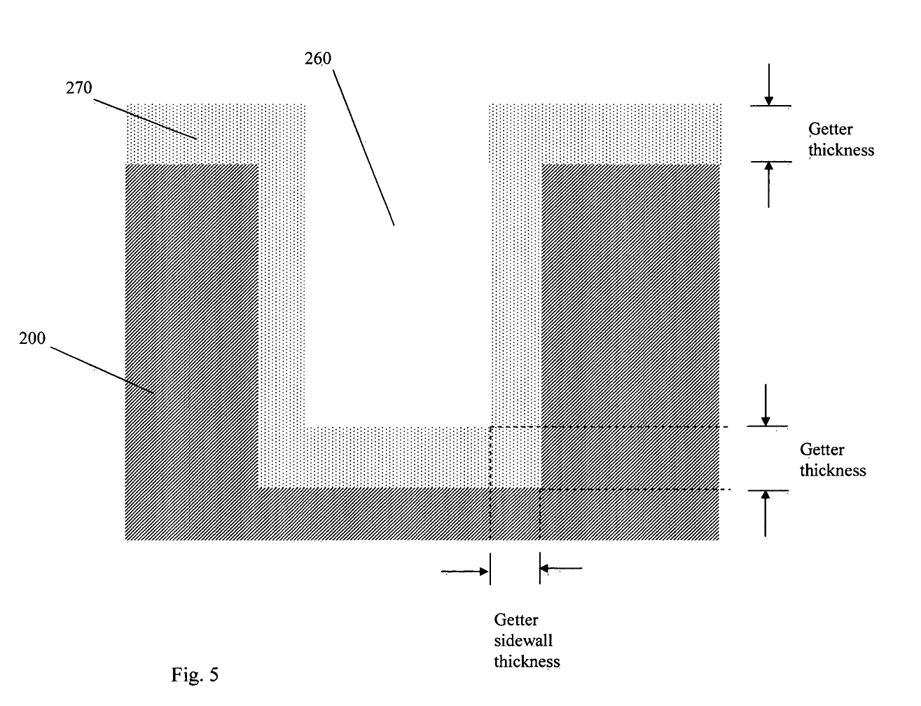

Having completed the formation of the lid wafer device cavity 220 with indentation features 260, the lid wafer 200 may then have the novel getter material 270 deposited thereon, as shown in FIG. 5. The constituents of the novel getter material may be chosen to have weight percentages in order to accomplish thermal matching of the materials, that is, the alloy may be designed to have a CTE more closely match that of the wafer upon which it is deposited, while still maintaining the required gettering properties. For a silicon (or float zone silicon), the wafer may have a CTE of about 3 ppm per degree centigrade. However, for other substrate materials such as quartz or glass, the getter alloy may be chosen with different respective weight percentages. The weight percentages may be chosen so that while better matching the CTE of the substrate upon which they are deposited, they still function effectively as getter materials, absorbing contaminating species.

For example, to better match the 3 ppm per degree CTE of the silicon substrate, a getter material may be formed from constituent components zirconium (Zr), vanadium (V), titanium (Ti) and iron (Fe). A getter alloy containing the following mixture of components may be effective:

TABLE 1
Novel getter alloy

| | | Approx. weight |
|---|---|---|
| | CTE of component | percentage |
| ComponentCTE | (ppm per degree) | of component |
| Zr | 2.9 | 60 |
| V | 8.6 | 20 |
| Ti | 8.9 | 15 |
| Fe | 11.6 | 5 |

Such an alloy may have a closer match to the CTE of silicon than the prior art alloy of 50/25/15/10, as described in http://getters.com/ZirconiumVanadiumTitaniumIron.aspx, and manufactured by Getter Technologies International, Ltd., of Hong Kong. By “approximate weight percentage,” it should-be understood that a range of compositions around the nominal value may also be effective for the novel alloy, for example, Zr in a weight percentage of greater than about 50% and at most about 70% and Fe in a weight percentage of greater than about 2% and at most about 8% Fe.

The metals or metal alloys of the getter material may be formed by depositing the getter material 270 from an appropriately formed target. The target may be formed from metal powders which are weighed to have the appropriate weight ratios and then melted to form a metal alloy target with the intended stoichiometry. The target may be formed using vacuum arc remelting, wherein a plasma arc is used to melt the metal powders in a vacuum to form the target material. In vacuum arc remelting, the metal materials act as an electrode, and are melted by striking an arc between a charged electrode and the metal materials. The arc beam may be rastered around the target with an electric field generated by another pair of parallel plates, for example. A suitable vacuum arc remelting furnace is manufactured by Retech Systems LLC, of Ukiah, Calif. A target having the desired stoichiometry may be made from powders mixed in the appropriate weight percentages shown in Table 1. In one embodiment, the target is formed in a high vacuum, that eliminates air that would otherwise contaminate the getter target material.

The target material may then be deposited on the lid wafer by sputter deposition, vacuum evaporation or ion beam deposition. A shadow mask may be used over the prepared lid wafer 200, to deposit the getter material 270 into the device cavities 220. Magnetron sputtering, evaporation or ion beam deposition are preferred methods because the getter material 270 may be deposited in a high vacuum (low pressure). When deposited under these conditions, the getter has less gas incorporated into the getter material 270. Large amounts of gas incorporated in the getter material 270 may reduce the ability of the getter material 270 to absorb additional gas, because it may be closer to saturation. A pressure below 10 mTorr is desirable for getter deposition, and the gas within the getter deposition chamber may be an inert gas, such as argon, nitrogen, xenon, krypton or neon, with xenon and krypton being more preferable. Deposition rates of about 20 angstroms/sec are typical.

The novel getter film 270 may be deposited over the indentation features substantially uniformly, as shown in FIG. 5, forming a film about 2 μm thick on the top surface and blind end of the indentation feature 260, and a film about half this thickness, or about 1 μm along the sidewalls of the indentation feature 260. More generally, the novel getter film 270 may be between about 0.5 μm to about 3 μm thick. At thinner film thicknesses, the amount of impurity gas absorbed may be reduced. At thicker film thicknesses, the novel getter film 270 may tend to delaminate from the lid wafer 200, even with the novel alloy formulation, and require longer deposition times without substantially improving the getter sorption properties. In general, as the aspect ratio of the indentation feature becomes bigger, the thickness of the novel getter film 270 on the sidewall becomes thinner. As was mentioned previously, indentation features with aspect ratios of about 2 to 1 are appropriate in shape for the deposition of a continuous novel getter film 270 by sputter deposition or vacuum evaporation. Other deposition techniques may allow larger aspect ratios, for example, directional deposition techniques, such as ion beam sputter deposition may be applied and the wafer rotated to obtain a continuous film within a relatively deep indentation feature 260.

The novel getter film 270 may be deposited with a layer of gold (not shown) covering the novel getter film 270. The purpose of the gold film may be to prevent the getter film from absorbing impurity gasses and becoming saturated, before it is installed in the device cavity 220 over the microdevice 120. After installation in the device cavity 220 as described below, the novel getter film 270 with the gold layer may be heated to a temperature at which the gold film diffuses into the novel getter film 270, exposing the surface of the getter film to the environment in the device cavity 220. At this point, the getter film may begin its operation. Alternatively, the novel getter film 270 on the lid wafer 200 may be heated to desorb any absorbed gases, before, after or during installation and bonding with the devices 120 on the device wafer 100. This activation of the novel getter film 270 may require temperatures of about 450 degrees centigrade, as described further below.

Having deposited the novel getter film 270 over the indented lid wafer 200, the lid wafer 200 is ready for assembly with the device wafer 100. The lid wafer 200 may first be aligned to the device wafer 100, so that the device cavity 220 is properly registered over the device 120. With the lid wafer 200 in the adjusted position relative to the device wafer 100, the lid wafer 200 may be clamped to the device wafer 100, to form a wafer assembly 300, shown in FIG. 6. Although for simplicity, the novel getter film 270 is not shown in FIG. 6, it should be understood that the novel getter film 270 may have been deposited over the indentation features 260 in the lid wafer 200 as was shown in FIG. 5. The wafer assembly 300 may then be loaded into a wafer bonding tool, which is then evacuated or may have the ambient air replaced with a preferred gas environment. Useful gas environments may include sulfur hexafluoride (SF₆), nitrogen (N₂), helium (He), argon (Ar), and neon (Ne). The environment may include vacuum and partial vacuum and high gas pressures, in excess of an atmosphere. In the case of the low pressure environments, the novel getter film 270 may operate to reduce or eliminate unwanted contaminants such as oxygen, water vapor, carbon oxides and organics such as methane from the gas environment. In the case of the vacuum or partial vacuum environment, the novel getter film 270 may operate to reduce the overall base pressure in the device cavity 220, due to outgassing of various impurities from the lid wafer 200 or device wafer 100, or from the components of the devices 120. In a higher pressure noble gas environment, the getter may be used to remove unwanted impurities from the environment.

The wafer bonding tool may be equipped with a wafer chuck to hold the wafer assembly 300 and a pressure chuck which may apply pressure to the wafer assembly 300. The wafer bonding tool may also have a heat source, which may apply heat to the adhesive that may bond the lid wafer 200 to the device wafer 100, and activate the novel getter film 270. For example, if the adhesive is a glass frit, the wafer bonding tool may heat the wafer assembly 300 to a temperature of about 450 degrees centigrade for at least about 10 minutes, and apply a force between the lid wafer 200 and the device wafer 100 of about 50 N to about 4000 N. This heating step for sealing the adhesive may also serve to diffuse the gold layer over the getter film 270, as described above, and/or activate the getter film 270. By using the novel getter alloy, the getter film 270 may have a reduced tendency to delaminate from the lid wafer 200 during this heating step. After the lid wafer 200 is sealed with the device wafer 100, enclosing either the preferred gas or vacuum within the device cavity 220, the wafer assembly 300 may be removed from the wafer bonding tool. The individual devices 120 may then be singulated from the device wafer 100 by sawing or grinding, for example, to form the encapsulated individual device packages.

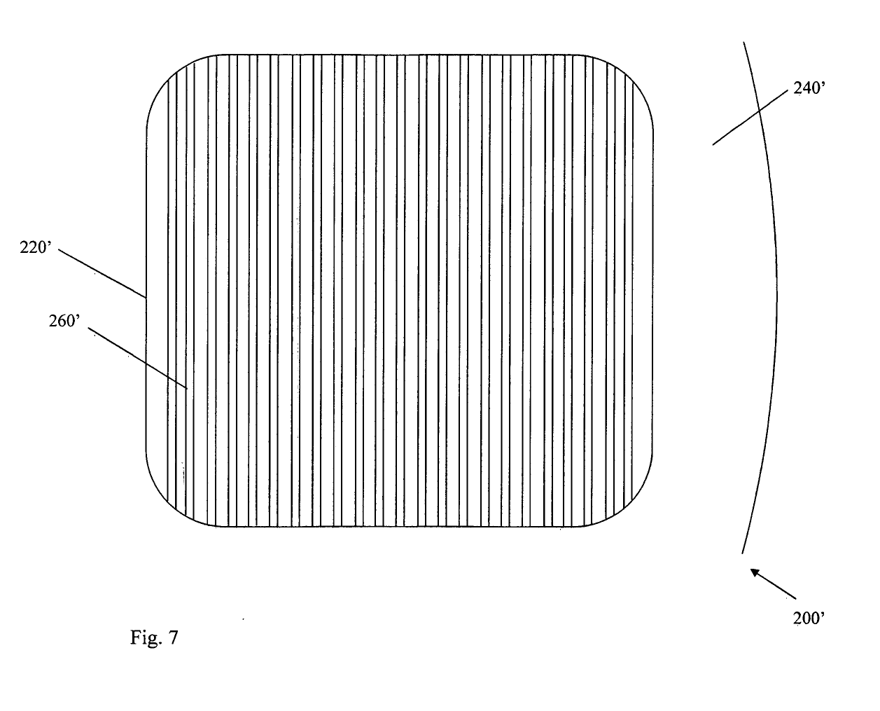

Although the indented lid 200 is shown in FIGS. 2 and 3 as containing an array of identical circular blind holes 260, it should be understood that this embodiment is exemplary only, and that the shapes patterned into the indented lid 200 may be any of a variety of shapes. FIG. 7 is a plan view of an exemplary lid wafer 200′ according to a second exemplary embodiment. In this embodiment, the indentation features 260′ are grooves rather than the blind holes of the first exemplary embodiment. The dimensions of the grooves 260′ may be similar in cross section to the blind holes 260 of the first exemplary embodiment, about 6 μm wide and 8 μm deep and as shown in FIG. 4, however, the grooves 260′ may extend across the entire surface of the device cavity 220′. The pitch between the grooves may also be similar, about 6 to about 250 μm or more. It should be understood that although the systems and methods are described with respect to a blind hole embodiment and a grooved embodiment, these embodiments are exemplary only, and that other shapes may be employed which increase the surface area of the deposited getter. Such other shapes of the indentations may be, for example, trapezoidal or sinusoidal trenches, and may also depend on the processing techniques used to form the indentation features 260. For example, a wet etch may be used to form a saw tooth pattern with 57 degree sidewall slopes in the surface of the device cavity. Accordingly, a wide range of techniques may result in a wide range of shapes of the indentation features, which may be covered with the novel getter film 270. Each of these examples of indentation features may improve the gettering performance within the device cavity 220, especially when combined with the novel getter formulation.

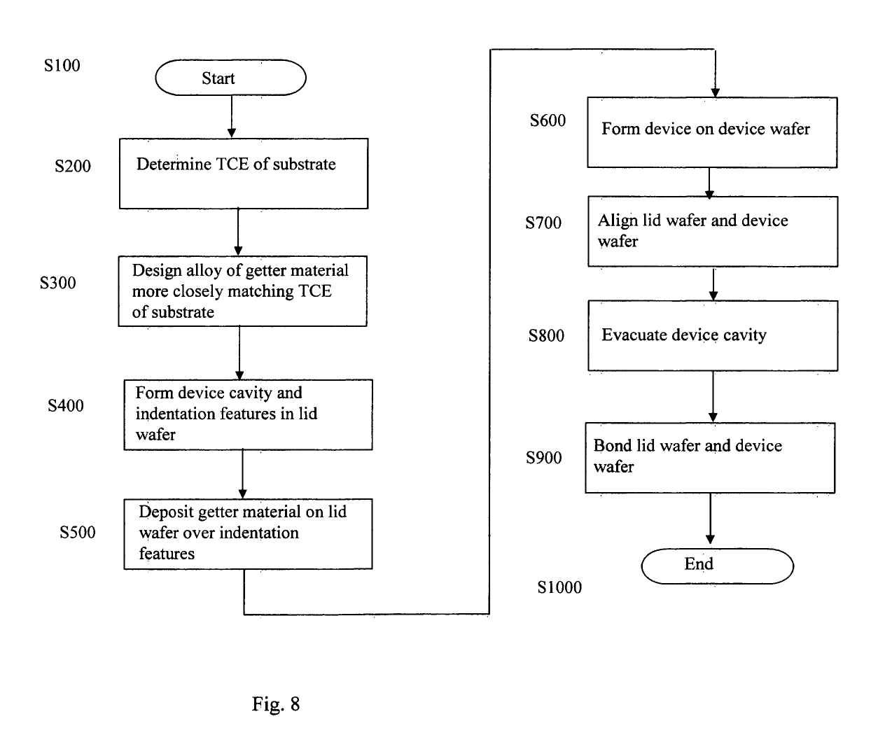

FIG. 8 is an exemplary flow chart describing a method for manufacturing an encapsulated device. The method begins in step S100 and proceeds to step S200, wherein the CTE of the substrate material is determined. In step S300, a stoichiometry is determined for a getter material that more closely matches the CTE of the substrate material. A lid wafer with indentation features in a device cavity is fabricated in step S400. In step S500, the getter material is deposited over the indented lid wafer formed with the device cavity therein. In various exemplary embodiments, the getter material may be deposited by vacuum evaporation through a shadow mask, for example. In step S600, a microdevice is formed on the device wafer. The device may be formed by any number of bulk machining or surface machining techniques, for example, sputtering, plating and etching. In step S700, the lid wafer is aligned with the device wafer so that the device cavity is registered over the device, and the wafers may be clamped together in a wafer assembly. In step S800, the device cavity is evacuated, and the gas environment within the wafer bonding tool may be replaced with a preferred gas, or by vacuum. In step S900, lid wafer is bonded to the device wafer using, for example, a glass frit adhesive, thereby heating and activating the novel getter material. The process ends in step S1000.

It should be understood that the steps shown in FIG. 10 need not necessarily be performed in the order indicated. For example, the indentation features may be formed before the device cavity, rather than after, and the microdevice may be formed on the device wafer before fabrication of the lid wafer with the device cavity. Also, not all of the steps may be required to perform the method, for example, the devices may not necessarily be evacuated but the device cavities may instead be filled with a preferred gas environment.

The systems and methods described here may result in improved getter performance because novel getter alloy may have a CTE which is more closely matched to that of the substrate, therefore reducing the tendency of the getter film to delaminate, especially when disposed over indentation features. Such indentation features may increase the surface area of the getter which is exposed to the environment in the device cavity.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. For example, while the systems and methods are described with respect to a system using an array of blind holes formed in a lid wafer as the indentation features, it should be understood that this embodiment is exemplary only, and that the systems and methods disclosed here may be applied to any number of alternative shapes for providing indentation features, or even an unindented lid, or a lid or device wafer with no cavity, wherein the lid wafer is held aloft from the device wafer by a rigid standoff. The systems and methods may also be applied to a device and lid system comprising 3 or more bonded substrates. Furthermore, the indented features may be formed by depositing material on the wafer surface, as well as removing material from the wafer surface. Accordingly, the exemplary implementations set forth above, are intended to be illustrative, not limiting.

What is claimed is:

1. A method for manufacturing an encapsulated microdevice, comprising:
forming a getter material in a device cavity defined by two substrates, the getter material having component percentages of at most about 8% by weight of iron and greater than about 50% by weight of zirconium, and a balance including titanium and vanadium; and
enclosing the microdevice in the device cavity.

2. The method of claim 1, wherein the getter material comprises zirconium, vanadium, titanium and iron in weight percentages of about 60/25/10/5, respectively.

3. The method of claim 1, further comprising:
forming the microdevice on a device wafer;
forming the device cavity in a lid wafer; and
enclosing the microdevice in the device cavity by bonding the lid wafer to the device wafer.

4. The method of claim 3, further comprising:
forming a plurality of indentation features on at least one of the lid wafer and the device wafer within the device cavity; and
forming a layer of getter material over at least a portion of the indentation features.

5. The method of claim 4, wherein forming the layer of getter material comprises depositing the getter material by at least one of vacuum evaporation and sputter deposition.

6. The method of claim 4, further comprising:
aligning the device wafer to the lid wafer such that the device cavity in the lid wafer is located over the microdevice on the device wafer;
evacuating the device cavity; and
bonding the lid wafer to the device wafer.

7. The method of claim 6, further comprising:
adding a gas to the evacuated cavity, wherein the gas includes at least one of sulfur hexafluoride (SF₆), helium (He), nitrogen (N₂), argon (Ar), and neon (Ne).

8. The method of claim 4, wherein forming the plurality of indentation features further comprises forming the plurality of indentation features using at least one of deep reactive ion etching, wet etching, ion milling, dry etching, stamping, molding, electroplating and ion beam deposition.

9. An encapsulated microdevice, comprising:
a microdevice formed on a first substrate and enclosed in a device cavity; and
a getter material disposed in the device cavity, the getter material having component percentages of at most about 8% by weight of iron and greater than about 50% by weight of zirconium, and a balance including titanium and vanadium.

10. The encapsulated microdevice of claim 9, wherein the getter material comprises less than about 70% by weight of zirconium and at least about 2% by weight of iron.

11. The encapsulated microdevice of claim 10, wherein the getter material comprises a layer of a ZrN/Ti/Fe alloy with constituent metals having weight percentages of about 60/25/10/5, respectively.

12. The encapsulated microdevice of claim 9, further comprising:
a plurality of indentation features formed on a surface of the device cavity.

13. The encapsulated microdevice of claim 12, wherein the getter material is formed over at least a portion of the plurality of indentation features.

14. The encapsulated microdevice of claim 9, wherein the device cavity is formed by bonding a second substrate to the first substrate, and wherein the first substrate and the second substrate each comprises at least one of glass, a nickel-cobalt alloy, a nickel-iron alloy, silicon, and ceramic.

15. The encapsulated microdevice of claim 12, wherein the plurality of indentation features comprises an array of blind holes, each with an aspect ratio of about 2 to 1.

16. The encapsulated microdevice of claim 15, wherein the blind holes have a diameter of between about 5 microns and 10 microns, and a depth of about 8 microns to about 20 microns.

17. The encapsulated device of claim 9, wherein the getter material is formed in a layer between about 0.5 μm and about 3 μm thick.

18. The encapsulated microdevice of claim 9, wherein the microdevice comprises at least one of a MFMS actuator, a MEMS sensor, an IR emitter, an IR detector, and an integrated circuit.

19. The encapsulated microdevice of claim 14, wherein the second substrate is hermetically bonded to the first substrate with a glass frit seal.

20. The encapsulated microdevice of claim 19, wherein the device cavity contains at least one of sulfur hexafluoride (SF₆), helium (He), nitrogen (N₂), argon (Ar), neon (Ne), vacuum, and partial vacuum.
